(19) United States
(12) Patent Application Publication
(10) Pub. No.: US 2026/0136812 A1
(43) Pub. Date: May 14, 2026

(54) DISPLAY PANEL, METHOD FOR PREPARING DISPLAY PANEL, AND DISPLAY DEVICE

(71) Applicants: Hefei Visionox Technology Co., Ltd., Hefei (CN); Visionox Technology Inc., Kunshan (CN)

(72) Inventors: Zhiwei ZHOU, Hefei (CN); Jinfang ZHANG, Hefei (CN); Guodong LIU, Hefei (CN); Lu ZHANG, Kunshan (CN)

(73) Assignees: Hefei Visionox Technology Co., Ltd., Hefei (CN); Visionox Technology Inc., Kunshan (CN)

(21) Appl. No.: 19/386,130

(22) Filed: Nov. 11, 2025

(30) Foreign Application Priority Data
Nov. 13, 2024 (CN) 202411621549.2

(51) Int. Cl. H10K 59/80; H10K 59/12; H10K 59/122; H10K 59/124; H10K 59/131; H10K 102/00

(52) U.S. Cl. CPC H10K 59/8731; H10K 59/1201; H10K 59/122; H10K 59/124; H10K 59/131; H10K 2102/351

(57) ABSTRACT

The present application relates to a display panel and a preparing method thereof, and a display device. The display panel includes a substrate, an insulation structure, an isolation structure, a plurality of light-emitting elements and a first inorganic encapsulation layer; the substrate includes an active and a hole area; the isolation structure is disposed on one side of the substrate, the isolation structure defines a plurality of isolation openings, and the plurality of isolation openings are located in the active area; each of the light-emitting elements is at least partially disposed inside a corresponding one of the isolation openings; and the first inorganic encapsulation layer covers at least part of a top surface on a side of the isolation structure away from the substrate, the first inorganic encapsulation layer includes a first end surface close to the hole area, and the first end surface is spaced from the hole area.

### CROSS-REFERENCE TO RELATED APPLICATIONS

The present application claims priority to Chinese Patent Application No. 202411621549.2, titled “DISPLAY PANEL, METHOD FOR PREPARING DISPLAY PANEL, AND DISPLAY DEVICE” and filed on Nov. 13, 2024, which is hereby incorporated by reference in its entirety.

### FIELD

The present application relates to the field of display, and in particular to a display panel, a method for preparing a display panel and a display device.

### BACKGROUND

Owing to the characteristics of self-luminescence, high luminance, wide viewing angle, high contrast, flexibility, low energy consumption, etc., an organic light-emitting diode (OLED) has attracted wide attention, and as a new generation of display modes, it has begun to gradually replace a conventional liquid crystal display, and has been widely used in mobile phone screens, computer monitors, full-color televisions, etc.

During the preparation of conventional OLED display panels, light-emitting pixel patterning is usually implemented by means of a fine metal mask (FMM). FMM technology is mature and has rich experience in mass production. However, FMM technology also has problems such as limited accuracy, and high costs. Fine metal mask-free technology eliminates the limitations of conventional OLED processes on display size, resolution, and other screen performances, and has the advantages of high performance, full-size coverage, and agile delivery. Patents CN118251982A, CN115666161A, CN116648095A, CN117062489A, CN118678742A, CN118785761A, CN115224220A, CN118678729A, CN118660529A and CN118660589A describe contents related to the fine metal mask-free technology for reference.

However, the current OLED display panel has the problem of poor reliability.

### SUMMARY

Based on this, the present application provides a display panel, a method for preparing a display panel, and a display device to improve the reliability of the display panel.

In one embodiment of the present application, an embodiment provides a display panel, including:
a substrate including an active area and a hole area;
an isolation structure disposed on one side of the substrate, the isolation structure defining a plurality of isolation openings, and the plurality of isolation openings being located in the active area;
a plurality of light-emitting elements, each of the light-emitting elements being at least partially disposed inside a corresponding one of the isolation openings; and
a first inorganic encapsulation layer covering at least part of a top surface on a side of the isolation structure away from the substrate, the first inorganic encapsulation layer including a first end surface close to the hole area, and the first end surface being spaced from the hole area.

In one embodiment of the present application, an embodiment provides a method for preparing a display panel, including:
providing a substrate, the substrate including an active area and a hole area;
forming an isolation structure located on one side of the substrate, the isolation structure defining a plurality of isolation openings located in the active area;
forming a plurality of light-emitting elements located inside the plurality of isolation openings; and
forming a first inorganic encapsulation layer covering at least part of a top surface on a side of the isolation structure away from the substrate, where the first inorganic encapsulation layer includes a first end surface close to the hole area, and the first end surface is spaced from the hole area.

In one embodiment of the present application, an embodiment provides a display device, including a display panel, the display panel including:
a substrate including an active area and a hole area;
an isolation structure disposed on one side of the substrate, the isolation structure defining a plurality of isolation openings, and the plurality of isolation openings being located in the active area;
a plurality of light-emitting elements, each of the light-emitting elements being at least partially disposed inside a corresponding one of the isolation openings; and
a first inorganic encapsulation layer covering at least part of a top surface on a side of the isolation structure away from the substrate, the first inorganic encapsulation layer including a first end surface close to the hole area, and the first end surface being spaced from the hole area. In this way, the reliability of the display device can be improved.

### BRIEF DESCRIPTION OF THE DRAWINGS

FIG. 1 is a plan view of a display panel according to some embodiments of the present application;

FIG. 2 is a sectional view of an active area and a non-active area of the display panel shown in FIG. 1;

FIG. 3 is a sectional view of the active area of the display panel shown in FIG. 1;

FIG. 4 is a sectional view of the display panel shown in FIG. 1;

FIG. 5 is another sectional view of the display panel shown in FIG. 1;

FIG. 6 is a further sectional view of the display panel shown in FIG. 1;

FIG. 7 is a yet further sectional view of the display panel shown in FIG. 1;

FIG. 8 is a structural schematic diagram of a drive transistor in the display panel shown in FIG. 3;

FIG. 9 is a flowchart of a method for preparing a display panel according to some embodiments of the present application;

FIG. 10 is another flowchart of the method for preparing a display panel according to some embodiments of the present application; and

FIG. 11 is a structural schematic diagram of a display device according to some embodiments of the present application.

### List of Reference Signs

1. Display device; 10. Display panel; 11. Substrate; 11 a. Active area; 11 b. Non-active area; 11c. Hole area; 13. Isolation structure; 13a. Isolation opening; 131. Isolation portion; 132. Lap joint portion; 14. Light-emitting element; 14a. First light-emitting element; 14b. Second light-emitting element; 141. First electrode; 142. Light-emitting functional layer; 143. Second electrode; 15. First inorganic encapsulation layer; 15a. First end surface; 16. Second inorganic encapsulation layer; 161. Second inorganic encapsulation structure; 161a. First inorganic encapsulation sub-structure; 161b. Second inorganic encapsulation sub-structure; 17. Organic encapsulation layer; 17a. Second end surface; 18. Third inorganic encapsulation layer; 18a. Third end surface; 19. Dam structure; 20. Pixel defining layer; 201. Pixel defining portion; 201a. Pixel opening; 201b. Fourth end surface; 21. Array layer; 211. Inorganic insulation sub-layer; 2111. First inorganic insulation sub-layer; 212. Trench; 213. Drive transistor; 2131. First terminal; 2132. Gate; 2133. Semiconductor layer; 2134. Second terminal; 214. Trace connection structure; 215. Organic insulation sub-layer; 216. Recessed portion.

### DETAILED DESCRIPTION OF THE EMBODIMENTS

The organic light-emitting diode (OLED) display technology is regarded as the most promising novel flat panel display technology of the next generation. Compared with the liquid crystal display technology, the OLED display technology has the advantages of low energy consumption, low cost, self-luminescence, wide viewing angle, fast response, etc. In a related OLED display panel, a substrate is provided with an isolation structure, and the isolation structure defines an isolation port. Sub-pixels are disposed at the isolation port, and a cathode of each sub-pixel is electrically connected to the isolation structure. The sub-pixels are fabricated sequentially using a patterning process, and each of the sub-pixels is protected by a corresponding encapsulation portion in the patterning process. In order to improve the screen-to-body ratio of the OLED display panel, an aperture may be formed in the OLED display panel, and an under-screen optical device is disposed inside the aperture. However, such an OLED display panel has the problem of poor reliability.

After research, it was found by the inventor that inorganic cracking tends to occur in the process of cutting the aperture in the OLED display panel, resulting in an area near the aperture being susceptible to an encapsulation failure, which affects the reliability of the OLED display panel.

In order to solve the above problem, embodiments of the present application provide a display panel and a preparing method thereof, and a display device. Various embodiments will be described below with reference to the drawings.

Referring to FIGS. 1 to 4, in one embodiment of the present application provides a display panel 10. The display panel 10 may be an organic light-emitting diode (OLED) display panel or a quantum dot light-emitting diode (QLED) display panel.

Specifically, the display panel 10 includes a substrate 11, an isolation structure 13, a plurality of light-emitting elements 14 and a first inorganic encapsulation layer 15; the substrate 11 includes an active area 11a and a hole area 11c; the isolation structure 13 is disposed on one side of the substrate 11, the isolation structure 13 defines a plurality of isolation openings 13a, and the plurality of isolation openings 13a are located in the active area 11a; each of the light-emitting elements 14 is at least partially disposed inside a corresponding one of the isolation openings 13a; and the first inorganic encapsulation layer 15 covers at least part of a top surface on a side of the isolation structure 13 away from the substrate 11, the first inorganic encapsulation layer 15 includes a first end surface 15a close to the hole area 11c, and the first end surface 15a is spaced from the hole area 11c.

In the display panel 10 provided by the embodiment of the present application, the first inorganic encapsulation layer 15 is provided and the first inorganic encapsulation layer 15 covers at least part of the top surface on the side of the isolation structure 13 away from the substrate 11, and the first end surface 15a of the first inorganic encapsulation layer 15 close to the hole area 11c is spaced from the hole area 11c. In this way, when an aperture is formed in the hole area 11c of the display panel 10, the risk of cracking of the first inorganic encapsulation layer 15 can be reduced, and the encapsulation reliability of the first inorganic encapsulation layer 15 can be enhanced, and the reliability in encapsulating the display panel 10 can be improved, thereby enhancing the reliability of the display panel 10.

It should be noted that, referring to FIG. 1, the active area 11a may be disposed around the hole area 11c.

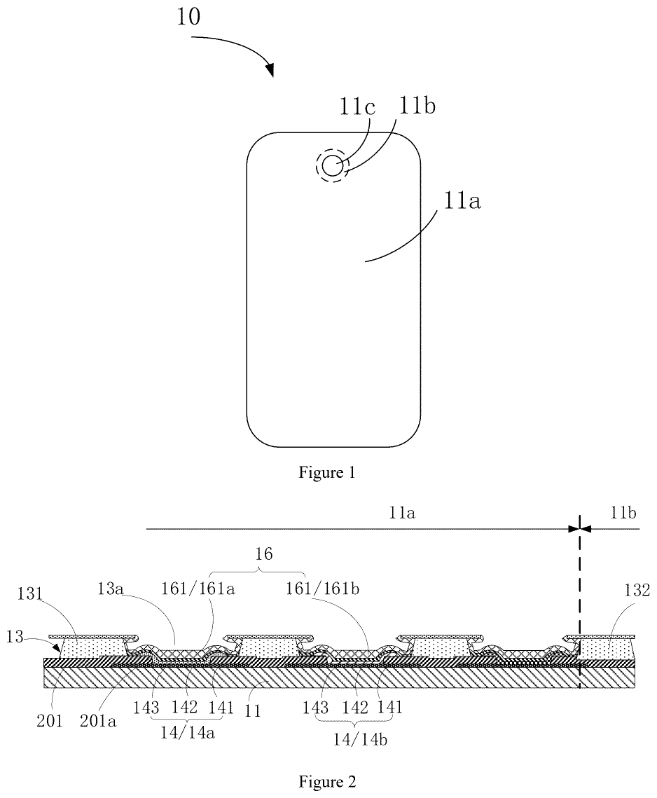

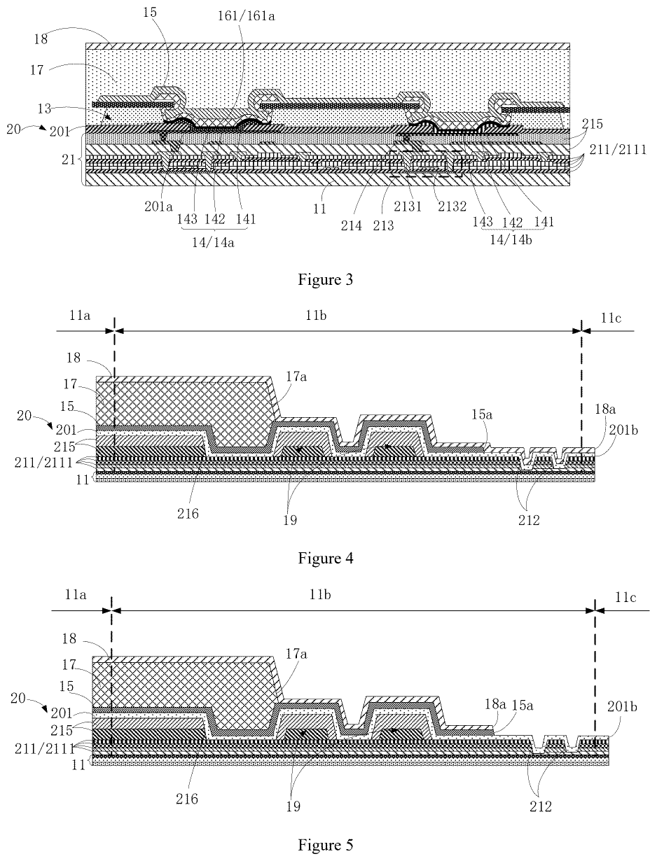

Referring to FIGS. 2 and 3, in an embodiment, the display panel 10 further includes a second inorganic encapsulation layer 16 including a plurality of second inorganic encapsulation structures 161, and each of the second inorganic encapsulation structures 161 covers a surface on a side of a corresponding one of the light-emitting elements 14 away from the substrate 11; and the first inorganic encapsulation layer 15 is located on a side of the second inorganic encapsulation layer 16 away from the substrate 11.

In this way, the second inorganic encapsulation structure 161 can provide independent encapsulation for the light-emitting element 14, and the probability of failure of the light-emitting element 14 is reduced, and the display reliability of the display panel 10 is improved, which in turn can improve the reliability of the display panel 10.

Referring to FIGS. 2 and 3, in an embodiment, the first inorganic encapsulation layer 15 covers surfaces on sides of the plurality of second inorganic encapsulation structures 161 away from the substrate 11.

In this way, the first inorganic encapsulation layer 15 and the second inorganic encapsulation structures 161 can provide double-layer encapsulation protection for the light-emitting element 14, thereby further reducing the probability of failure of the light-emitting element 14 and improving the display reliability of the display panel 10, which in turn can improve the reliability of the display panel 10.

Referring to FIG. 4, in an embodiment, the display panel 10 further includes an organic encapsulation layer 17 and a third inorganic encapsulation layer 18, the organic encapsulation layer 17 is located on a side of the first inorganic encapsulation layer 15 away from the substrate 11, and the organic encapsulation layer 17 includes at least one second end surface 17a; the third inorganic encapsulation layer 18 is located on a side of the organic encapsulation layer 17 away from the substrate 11; and the at least one second end surface 17a is covered by the third inorganic encapsulation layer 18 and the first inorganic encapsulation layer 15.

In this way, the probability of moisture invading the active area 10a of the display panel 10 through the organic encapsulation layer 17 can be reduced. In addition, the first inorganic encapsulation layer 15, the second inorganic encapsulation layer 16, the organic encapsulation layer 17 and the third inorganic encapsulation layer 16 can form four-layer encapsulation of the display panel 10, thereby effectively improving the reliability in encapsulating the display panel 10, which in turn improves the reliability of the display panel 10.

Referring to FIG. 5, in an embodiment, the third inorganic encapsulation layer 18 includes a third end surface 18a close to the hole area 11c, and the third end surface 18a is aligned with the first end surface 15a.

In other words, the third end surface 18a and the first end surface 15a are located in the same plane.

In one embodiment, the risk of cracking of the third inorganic encapsulation layer 18 in the process of forming an aperture in the hole area 11c can be reduced, thereby improving the reliability in encapsulating the display panel 10; and in another embodiment, the first inorganic encapsulation layer 15 and the third inorganic encapsulation layer 18 can be etched in the same process, thereby decreasing the number of masks used, reducing preparation procedures of the display panel 10 and lowering the production cost of the display panel 10.

It should be noted that the plane may be a plane that is perpendicular to a direction in which the active area 11a points to the hole area 11c and perpendicular to the substrate.

Referring to FIG. 4, in an embodiment, the third inorganic encapsulation layer 18 includes a third end surface 18a close to the hole area 11c, and the third end surface 18a coincides with an edge of the hole area 11c.

In this way, the third inorganic encapsulation layer 18 can encapsulate the display panel, thereby improving the reliability in encapsulating the display panel 10, which in turn improves the reliability of the display panel 10.

In an embodiment, the first end surface 15a is spaced from the hole area 11c by no less than 30 um.

That is, where permissible, the first end surface 15a of the first inorganic encapsulation layer 15 is kept as far away as possible from the hole area 11c, and the probability of cracking of the first inorganic encapsulation layer 15 is effectively reduced, and the reliability in encapsulating the display panel 10 is improved, thereby improving the reliability of the display panel 10.

In an embodiment, the first inorganic encapsulation layer 15 has a thickness ranging from 0.6 um to 1.5 um. For example, the thickness of the first inorganic encapsulation layer 15 may be 0.6 um, 0.7 um, 0.8 um, 0.9 um, 1.0 um, 1.1 um, 1.2 um, 1.3 um, 1.4 um, 1.5 um, or any value between 0.6 um and 1.5 um, which is not limited herein.

In this way, by setting the thickness of the first inorganic encapsulation layer 15 within the above range, the ability of the first inorganic encapsulation layer 15 to block moisture can be improved, and the encapsulation performance of the first inorganic encapsulation layer 15 can be improved, thereby improving the reliability in encapsulating the display panel 10, which in turn can improve the reliability of the display panel 10.

In an embodiment, the third inorganic encapsulation layer 18 has a thickness ranging from 0.6 um to 1.5 um. For example, the thickness of the third inorganic encapsulation layer 18 may be 0.6 um, 0.7 um, 0.8 um, 0.9 um, 1.0 um, 1.1 um, 1.2 um, 1.3 um, 1.4 um, 1.5 um, or any value between 0.6 um and 1.5 um, which is not limited herein.

In this way, by setting the thickness of the third inorganic encapsulation layer 18 within the above range, the ability of the third inorganic encapsulation layer 18 to block moisture can be improved, and the encapsulation performance of the third inorganic encapsulation layer 18 can be improved, thereby improving the reliability in encapsulating the display panel 10, which in turn can improve the reliability of the display panel 10.

Referring to FIGS. 4 and 5, in an embodiment, the display panel 10 is further provided with a non-active area 11b, the non-active area 11b being at least partially located between the active area 11a and the hole area 11c, and the display panel 10 further includes at least one dam structure 19, the at least one dam structure 19 being located in the non-active area 11b, and a distance between a surface on a side of the at least one dam structure 19 away from the substrate 11 and the substrate 11 being greater than a shortest distance between a surface on a side of the organic encapsulation layer 17 close to the substrate 11 and the substrate 11; where an orthographic projection of the first inorganic encapsulation layer 15 on the at least one dam structure 19 overlaps with an orthographic projection of the third inorganic encapsulation layer 18 on the at least one dam structure 19.

In this way, the first inorganic encapsulation layer 15 and the third inorganic encapsulation layer 18 can form two-layer encapsulation protection for the at least one dam structure 19, which can reduce the probability of moisture invading the active area 11a of the display panel 10 through the dam structure 19, thereby improving the reliability in encapsulating the display panel 10. In addition, the dam structure 19 can play a certain role in blocking the organic encapsulation layer 17 to reduce the probability of the organic encapsulation layer 17 overflowing to an undesired area (e.g., a side of the dam structure 19 away from the active area 10a), thereby reducing the probability of moisture invading the active area 11a through the organic encapsulation layer 17 and improving the reliability of the display panel 10.

Referring to FIGS. 4 and 5, in an embodiment, the first end surface 15a is located in the non-active area 11b between the at least one dam structure 19 and the hole area 11c.

That is, the first end surface 15a is located on a side of the at least one dam structure 19 away from the active area 11a, and the probability of moisture invading the active area 11a of the display panel 10 through the dam structure 19 can be further reduced, thereby improving the reliability in encapsulating the display panel 10, which in turn can improve the reliability of the display panel 10.

Referring to FIG. 5, in an embodiment, the third end surface 18a is aligned with the first end surface 15a, and the third end surface 18a is located in the non-active area 11b between the at least one dam structure 19 and the hole area 11.

That is, the first end surface 15a and the third end surface 18 are both located on the side of the at least one dam structure 19 away from the active area 11a, and the probability of moisture invading the active area 11a of the display panel 10 through the dam structure 19 can be further reduced, thereby improving the reliability in encapsulating the display panel 10. In addition, the first end surface 15a and the third end surface 18 can be obtained by etching the first inorganic encapsulation layer 15 and the third inorganic encapsulation layer 18 in the same process, thereby decreasing the number of masks used, reducing preparation procedures of the display panel 10 and lowering the production cost of the display panel 10.

Referring to FIG. 4, in an embodiment, the third end surface 18a coincides with an edge of the hole area 11c, and an orthographic projection of the third inorganic encapsulation layer 18 on the substrate 11 covers an orthographic projection of the at least one dam structure 19 on the substrate 11.

In this way, the reliability in encapsulating the non-active area 11b of the display panel 10 can be improved, thereby improving the reliability of the display panel 10.

Referring to FIGS. 2-5, in an embodiment, the display panel 10 further includes a pixel defining layer 20, where the pixel defining layer 20 is located in the active area 11a and the non-active area 11b, the pixel defining layer 20 includes a pixel defining portion 201, the pixel defining portion 201 defines a plurality of pixel openings 201a, each of the pixel openings 201a is in communication with a corresponding one of the isolation openings 13a, and the light-emitting element 14 is at least partially disposed inside a corresponding one of the pixel openings 201a; the pixel defining portion 201a is located on a side of the first inorganic encapsulation layer 15 close to the substrate 11; and the pixel defining portion 201 covers at least part of a surface on a side of the at least one dam structure 19 away from the substrate 11, and an orthographic projection of the pixel defining portion 201 on the at least one dam structure 19 overlaps with an orthographic projection of the first inorganic encapsulation layer 15 on the at least one dam structure 19.

In this way, the pixel defining portion 201 and the first inorganic encapsulation layer 15 can encapsulate the at least one dam structure 19, which can further reduce the probability of moisture invading the active area 11a of the display panel 10 through the dam structure 19, thereby further improving the reliability in encapsulating the display panel 10 and improving the reliability of the display panel 10.

In an embodiment, the at least one dam structure 19 is disposed around the active area 11a.

In this way, the dam structure 19 can effectively block the organic encapsulation layer 17 at the periphery of the active area 11a to effectively reduce the probability of the organic encapsulation layer 17 overflowing to an undesired area and to effectively reduce the probability of moisture invading the active area 11a through the organic encapsulation layer 17, thereby improving the reliability of the display panel 10.

Referring to FIGS. 2 to 7, in an embodiment, the display panel 10 is further provided with a non-active area 11b, and the non-active area 11b is at least partially located between the active area 11a and the hole area 11c. The display panel 10 further includes an array layer 21, the array layer 21 is disposed on one side of the substrate 11, and the array layer 21 includes a plurality of inorganic insulation sub-layers 211 and at least one trench 212. The plurality of inorganic insulation sub-layers 211 extend from the active area 11a to the non-active area 11b. The at least one trench 212 is located in the non-active area 11b and extends toward the substrate 11 from a side of the plurality of inorganic insulation sub-layers 211 away from the substrate 11. The first end surface 15a is located in the non-active area 11b between the at least one trench 212 and the active area 11a.

In this way, the trench 212 can block cracks of the inorganic insulation sub-layer 212 generated in the process of forming an aperture in the hole area 11c to reduce the probability that the cracks extend toward the active area 10a along the inorganic insulation sub-layer 212 and to reduce the probability of cracking of the first inorganic encapsulation layer 15, thereby improving the reliability in encapsulating the display panel 10, which in turn can improve the reliability of the display panel 10.

It should be noted that, referring to FIG. 2, the outermost light-emitting element may be regarded as a boundary between the active area and the non-active area, and when the plurality of light-emitting elements include both a non-virtual light-emitting element and a virtual light-emitting element, the outermost non-virtual light-emitting element may be regarded as the boundary between the active area and the non-active area. “The outermost light-emitting element” may be understood as the light-emitting element that is furthest from the center of the display panel 10; and when the plurality of light-emitting elements are of an array arrangement structure, “the outermost light-emitting element may refer to the light-emitting element located at the outermost periphery of the array arrangement structure. “Virtual light-emitting element” refers to a light-emitting element that does not emit light in the display panel, for example, a light-emitting element that is not connected to a drive transistor as described below. “Non-virtual light-emitting element” refers to a light-emitting element that normally emits light in the display panel, for example, a light-emitting element that is connected to the drive transistor as described below.

Referring to FIG. 5, in an embodiment, the third end surface 18a is aligned with the first end surface 15a, and the third end surface 18a is located in the non-active area 11b between the at least one trench 212 and the active area 11a.

In this way, the probability of cracking of the third inorganic encapsulation layer 18 can be reduced, thereby improving the reliability in encapsulating the display panel 10, which in turn can improve the reliability of the display panel 10.

Referring to FIGS. 4, 6 and 7, in an embodiment, the third end surface 18a coincides with an edge of the hole area 11a, and an orthographic projection of the third inorganic encapsulation layer 18 on the substrate 11 covers an orthographic projection of the at least one trench 212 on the substrate 11.

In this way, the amount of etching of the third inorganic encapsulation layer 18 can be reduced, which improves the preparation efficiency of the display panel 10.

Referring to FIGS. 4 to 7, in an embodiment, an orthographic projection of the first inorganic encapsulation layer 15 on the substrate 11 does not overlap with an orthographic projection of the at least one trench 212 on the substrate 11.

In this way, cracks in the inorganic insulation sub-layer 212 generated in the process of forming an aperture in the hole area 11c can be prevented from being transmitted to the first inorganic encapsulation layer 15 to reduce the probability of cracking of the first inorganic encapsulation layer 15, thereby improving the reliability in encapsulating the display panel 10, which in turn can improve the reliability of the display panel 10.

In an embodiment, the at least one trench 212 is disposed around the hole area.

In this way, the trench 212 can block the cracks of the inorganic insulation sub-layer 211 located at the periphery of the hole area 11 c to effectively reduce the probability that the cracks of the inorganic insulation sub-layer 211 extend toward the active area 11a along the inorganic insulation sub-layer 211, and the reliability in encapsulating the display panel 10 in the non-active area 11b can be improved, and the reliability in encapsulating the display panel 10 is improved, thereby improving the reliability of the display panel 10.

In an embodiment, the at least one trench 212 extends toward the substrate 11 by a first depth from the side of the plurality of inorganic insulation sub-layers 211 away from the substrate 11, the first depth ranging from 0.6 um to 1.5 um. For example, the first depth may be 0.6 um, 0.7 um, 0.8 um, 0.9 um, 1.0 um, 1.1 um, 1.2 um, 1.3 um, 1.4 um, 1.5 um, or any value between 0.6 um and 1.5 um, which is not limited herein.

In this way, by setting the first depth of the trench 212 within the above range, the trench 212 can better block the cracks of the inorganic insulation sub-layer 211 to reduce the probability that the cracks extend toward the active area 10a along the inorganic insulation sub-layer 212, thereby improving the reliability of the display panel 10.

Referring to FIGS. 3 to 8, in an embodiment, the array layer 21 further includes a plurality of drive transistors 213, a plurality of trace connection structures 214 and at least one organic insulation sub-layer 215. The display panel 10 further includes at least one dam structure 19. Each of the drive transistors 213 includes a semiconductor layer 2133, a gate 2132, and in one embodiment, a first terminal 2131 and/or a second terminal 2134. The semiconductor layer 2133, the gate 2132, and in one embodiment, the first terminal 2131 and/or the second terminal 2034 are spaced apart between the plurality of inorganic insulation sub-layers 211. The plurality of trace connection structures 214 are disposed in the at least one organic insulation sub-layer 215. The at least one organic insulation sub-layer 215 is located on the side of the plurality of inorganic insulation sub-layers 211 away from the substrate 11. Two ends of each of the plurality of trace connection structures 214 are respectively connected to the first terminals 2131 of a corresponding one of the drive transistors 215 and a corresponding one of the light-emitting elements 14. A distance between the substrate 11 and a surface on a side of the at least one dam structure 19 away from the substrate 11 is greater than a shortest distance between the substrate 11 and a surface on a side of the organic encapsulation layer 17 close to the substrate 11. The at least one dam structure 19 and the at least one organic insulation sub-layer 215 are disposed in the same layer.

In this way, not only normal light emission by the light-emitting element 14 but also normal display of the display panel 10 can be guaranteed. In addition, the organic insulation sub-layer 215 and the dam structure 19 can be prepared synchronously, thereby reducing the preparation procedures and cost of the display panel 10 and improving the preparation efficiency of the display panel 10.

It should be noted that the drive transistor 213 includes a semiconductor layer 2133 and a gate 2132, and in one embodiment, the drive transistor 213 further includes a first terminal 2131 and a second terminal 2134. The first terminal 2131 may be one of a source and a drain, and the second terminal 2134 may be the other of the source and the drain.

Referring to FIGS. 4 to 7, in an embodiment, at least one dam structure 19 is located in the non-active area 11b between the at least one trench 212 and the active area 11a.

In this way, the dam structure 19 may be kept away from the hole area 11c to reduce the probability that moisture from the hole area 11c invades the active area 11a of the display panel 10 through the dam structure 19, thereby improving the reliability of the display panel 10.

Referring to FIG. 5, in an embodiment, the third end surface 18a is aligned with the first end surface 15a, and the third end surface 18a is located in the non-active area 11b between the at least one dam structure 19 and the at least one trench 212.

In this way, cracks of the inorganic insulation sub-layer 211 generated in the process of forming an aperture in the hole area 11c can be prevented from being transmitted to the third inorganic encapsulation layer 18 to reduce the probability of cracking of the third inorganic encapsulation layer 18, thereby improving the reliability in encapsulating the display panel 10, which in turn can improve the reliability of the display panel 10.

Referring to FIGS. 3 to 7, in an embodiment, the plurality of inorganic insulation sub-layers 211 include a plurality of first inorganic insulation sub-layers 2111. The gates 2132 of the drive transistors 213 are located on a side of the plurality of first inorganic insulation sub-layers 2111 close to the substrate 11. The first terminals 2131 of the drive transistors 213 are located on a side of the plurality of first inorganic insulation sub-layers 2111 away from the substrate 11. The at least one trench 212 extends through the plurality of first inorganic insulation sub-layers 2111.

In this way, the plurality of first inorganic insulation sub-layers 2111 can be disconnected in the at least one trench 212, thereby preventing cracks of the plurality of first inorganic insulation sub-layers 2111 from extending toward the active area 11a along the first inorganic insulation sub-layers 2111, which in turn can improve the reliability of the display panel 10.

Referring to FIGS. 4 to 7, in an embodiment, the at least one dam structure 19 includes a plurality of dam structures 19, a recessed portion 216 is formed between the at least one dam structure 19 close to the at least one organic insulation sub-layer 215 and the organic insulation sub-layer 215, the recessed portion 216 is filled with the organic encapsulation layer 17, and a distance between the substrate 11 and a surface on a side of the at least one dam structure 19 away from the substrate 11 is greater than a distance between the substrate 11 and a surface on a side, close to the substrate 11, of the organic encapsulation layer 17 located in the recessed portion 216.

In this way, the plurality of dam structures 19 can provide multi-stage blocking for the organic encapsulation layer 17 to effectively reduce the probability of the organic encapsulation layer 17 overflowing to an undesired area and to effectively reduce the probability of moisture invading the active area 11a through the organic encapsulation layer 17, thereby improving the reliability of the display panel 10.

Referring to FIGS. 4 to 6, in an embodiment, the display panel 10 further includes a pixel defining layer 20. The pixel defining layer 20 is located in the active area 11a and the non-active area 11b and includes a pixel defining portion 201, the pixel defining portion 201 defines a plurality of pixel openings 201a, each of the pixel openings 201a is in communication with a corresponding one of the isolation openings 13a, and the light-emitting element 14 is at least partially disposed inside a corresponding one of the pixel openings 201a; the pixel defining portion 201 is located on a side of the first inorganic encapsulation layer 15 close to the substrate 11; and an orthographic projection of the pixel defining portion 201 on the substrate 11 covers an orthographic projection of the at least one trench 212 on the substrate 11.

In this way, the pixel defining portion 201 can encapsulate the non-active area 11b to improve the reliability in encapsulating the non-active area 11b, thereby improving the reliability of the display panel 10.

Referring to FIGS. 4 to 6, in an embodiment, the pixel defining portion 201 is at least in contact with a plurality of first inorganic insulation sub-layers 2111 located between the at least one dam structure 19 and the hole area 11c.

In this way, the pixel defining portion 201 is in contact with the first inorganic insulation sub-layer 2111 to encapsulate the at least one dam structure 19, thereby reducing the probability of moisture invading the active area 11a through the dam structure 19 and improving the reliability in encapsulating the display panel 10, which in turn can improve the reliability of the display panel 10.

Referring to FIG. 4, in an embodiment, the first inorganic encapsulation layer 15 is at least in contact with the pixel defining portion 201 located between the at least one dam structure 19 and the at least one trench 212.

In this way, the first inorganic encapsulation layer 15 and the pixel defining portion 201 can realize encapsulation of the non-active area 11b to improve the reliability in encapsulating the non-active area 11b of the display panel 10, thereby improving the reliability of the display panel 10.

Referring to FIGS. 4 and 5, in an embodiment, the third inorganic encapsulation layer 18 is at least in contact with the first inorganic encapsulation layer 15 located between the at least one dam structure 19 and the at least one trench 212.

In this way, the first inorganic encapsulation layer 15 and the third inorganic encapsulation layer 18 can realize encapsulation of the non-active area 11b to improve the reliability in encapsulating the non-active area 11b of the display panel 10, thereby improving the reliability of the display panel 10.

Referring to FIG. 4, in an embodiment, the third inorganic encapsulation layer 18 is also in contact with the pixel defining portion 201 located between the first end surface 15a and the hole area 11c.

In this way, the third inorganic encapsulation layer 18 and the pixel defining portion 201 can realize encapsulation of the non-active area 11b to improve the reliability in encapsulating the non-active area 11b of the display panel 10, thereby improving the reliability of the display panel 10.

Referring to FIGS. 3 and 6 to 8, in an embodiment, the display panel 10 is further provided with a non-active area 11b, the non-active area 11b being at least partially located between the active area 11a and the hole area 11c, and the display panel 10 further includes an array layer 21, the array layer 21 being disposed on one side of the substrate 11. The array layer 21 includes a plurality of drive transistors 213, a plurality of trace connection structures 214, a plurality of inorganic insulation sub-layers 211 and at least one organic insulation sub-layer 215. Each of the drive transistors 213 includes a semiconductor layer 2133, a gate 2132, and in one embodiment, a first terminal 2131 and/or a second terminal 2134. The semiconductor layer 2133, the gate 2132, and in one embodiment, the first terminal 2131 and/or the second terminal 2034 are spaced apart between the plurality of inorganic insulation sub-layers 211. The plurality of trace connection structures 214 are disposed in the at least one organic insulation sub-layer 215. Two ends of each of the plurality of trace connection structures 214 are respectively connected to the first terminals 2131 of a corresponding one of the drive transistors 213 and a corresponding one of the light-emitting elements 14. The at least one organic insulation sub-layer 215 is located on the side of the plurality of inorganic insulation sub-layers 211 away from the substrate 11. The plurality of inorganic insulation sub-layers 211 extend from the active area 11a to the non-active area 11b. The at least one dam structure 19 is located on the side of the plurality of inorganic insulation sub-layers 211 away from the substrate 11 and disposed in the same layer as the at least one organic insulation sub-layer 215, and the at least one dam structure 19 is located in the non-active area 11b between the at least one organic insulation sub-layer 215 and the hole area 11c. The first end surface 15a is located in the non-active area 11b between the at least one organic insulation sub-layer 215 and the at least one dam structure 19.

That is, the first inorganic encapsulation layer 15 can encapsulate only the active area 11a. In this way, even if the non-active area 11b fails in encapsulation, the active area 11a is not affected, thereby improving the reliability of the display panel 10.

In an embodiment, a distance between the first end surface 15a and the at least one dam structure 19 is not less than 5 um.

In this way, the preparation of the first inorganic encapsulation layer 15 is facilitated.

Referring to FIGS. 3 and 7, in an embodiment, the display panel 10 further includes a pixel defining layer 20, and the pixel defining layer 20 is located in the active area 11a and the non-active area 11b; the pixel defining layer 20 includes a pixel defining portion 201, the pixel defining portion 201 defines a plurality of pixel openings 201a, each of the pixel openings 201a is in communication with a corresponding one of the isolation openings 13a, and the light-emitting element 14 is at least partially disposed inside a corresponding one of the pixel openings 201a; the pixel defining portion 201 is located on a side of the first inorganic encapsulation layer 15 close to the substrate 11; and the pixel defining portion 201 includes a fourth end surface 201b close to the at least one dam structure 19, and the fourth end surface 201b is located in the non-active area 11b between the at least one organic insulation sub-layer 215 and the at least one dam structure 19.

In this way, the first inorganic encapsulation layer 15 and the pixel defining portion 201 can encapsulate the active area 11a, and the reliability in encapsulating the display panel 10 can be improved, thereby improving the reliability of the display panel 10.

Referring to FIGS. 3 to 6, in an embodiment, the display panel 10 further includes a pixel defining layer 20, where the pixel defining layer 20 is located in the active area 11a and the non-active area 11b, the pixel defining layer 20 includes a pixel defining portion 201, the pixel defining portion 201 defines a plurality of pixel openings 201a, each of the pixel openings 201a is in communication with a corresponding one of the isolation openings 13a, and the light-emitting element 14 is at least partially disposed inside a corresponding one of the pixel openings 201a; the pixel defining portion 201 is located on a side of the first inorganic encapsulation layer 15 close to the substrate 11; the organic encapsulation layer 17 is located on a side of the first inorganic encapsulation layer 15 away from the substrate 11; the third inorganic encapsulation layer 18 is located on a side of the organic encapsulation layer 17 away from the substrate 11; and the pixel defining portion 201 covers at least part of a surface on a side of the at least one dam structure 19 away from the substrate 11, and an orthographic projection of the pixel defining portion 201 on the at least one dam structure 19 overlaps with an orthographic projection of the third inorganic encapsulation layer 18 on the at least one dam structure 19.

In this way, the pixel defining portion 201 and the third inorganic encapsulation layer 18 can encapsulate the at least one dam structure 19 to reduce the probability of moisture invading the active area 11a through the dam structure 19 and to improve the reliability in encapsulating the non-active area 11b of the display panel 10, thereby improving the reliability of the display panel 10.

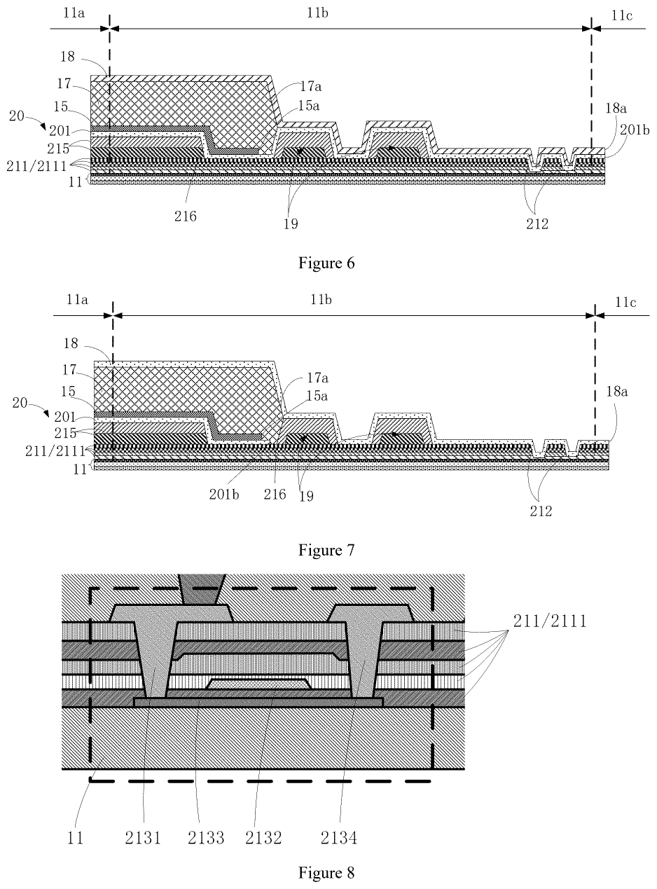

Referring to FIG. 6, in an embodiment, the organic encapsulation layer 17 includes at least one second end surface 17a, and the at least one second end surface 17a is covered by the third inorganic encapsulation layer 18 and the pixel defining portion 201.

In this way, the probability of moisture invading the active area 11a through the organic encapsulation layer 17 can be reduced, and the reliability in encapsulating the display panel 10 can be improved, thereby improving the reliability of the display panel 10.

Referring to FIG. 2, in an embodiment, the display panel 10 is further provided with a non-active area 11b, the non-active area 11b is at least partially located between the active area 11a and the hole area 11c, the isolation structure 13 includes an isolation portion 131 and a lap joint portion 132, and the isolation portion 131 defines a plurality of isolation openings 13a; the lap joint portion 132 is located in the non-active area 11b, and the lap joint portion 132 is connected with a power supply signal trace; and the first inorganic encapsulation layer 15 at least covers part of a top surface on a side of the lap joint portion 132 away from the substrate 11.

In this way, the isolation portion 131 may be connected with the power supply signal trace by means of the lap joint portion 132, and traces in the active area 11a of the display panel 10 can be reduced.

Referring to FIG. 2, in an embodiment, the light-emitting element 14 includes a first electrode 141, a light-emitting functional layer 142 and a second electrode 143 sequentially stacked in a direction away from the substrate 11, the second electrode 143 overlapping with the isolation portion 131.

Therefore, by electrically connecting the second electrode 143 to the isolation portion 131, which is equivalent to endowing the isolation portion 131 with a function of transmitting the power supply signal, thus traces in the active area 11a of the display panel 10 can be reduced.

It can be understood that the light-emitting functional layer 142 includes an emission layer (EML), and may further include one or more of a hole injection layer (HIL), a hole transport layer (HTL), an electron injection layer (EIL), an electron transport layer (ETL), a hole block layer (HBL), or an electron block layer (EBL). In one embodiment,, the light-emitting functional layer 142 may be a tandem light-emitting layer, that is, the light-emitting functional layer includes at least two emission layers and a charge generation layer (CGL) located between adjacent emission layers.

Referring to FIG. 3, in an embodiment, the plurality of light-emitting elements 14 include a first light-emitting element 14a and a second light-emitting element 14b, and the plurality of second inorganic encapsulation structures 161 include a first inorganic encapsulation sub-structure 161a and a second inorganic encapsulation sub-structure 161b, where the first inorganic encapsulation sub-structure 161a is disposed on a side of the first light-emitting element 14a away from the substrate 11 and extends from a side wall of the isolation structure 13 to a side of the isolation structure 13 away from the substrate 11, and the second inorganic encapsulation sub-structure 161b is disposed on a side of the second light-emitting element 14b away from the substrate 11 and extends from a side wall of the isolation structure 13 to the side of the isolation structure 13 away from the substrate 11; and an orthographic projection of the first inorganic encapsulation sub-structure 161a on the isolation structure 13 is located outside an orthographic projection of the second inorganic encapsulation sub-structure 161b on the isolation structure 13, and the first inorganic encapsulation layer 15 covers at least part of a top surface on a side, away from the substrate 11, of the isolation portion 131 located between the first inorganic encapsulation sub-structure 161a and the second inorganic encapsulation sub-structure 161b.

In this way, the reliability in encapsulating the active area 11a of the display panel 10 can be improved, the probability of failure of the light-emitting element 14 can be reduced, the display effect of the display panel 10 can be improved, and the reliability of the display panel 10 can be improved.

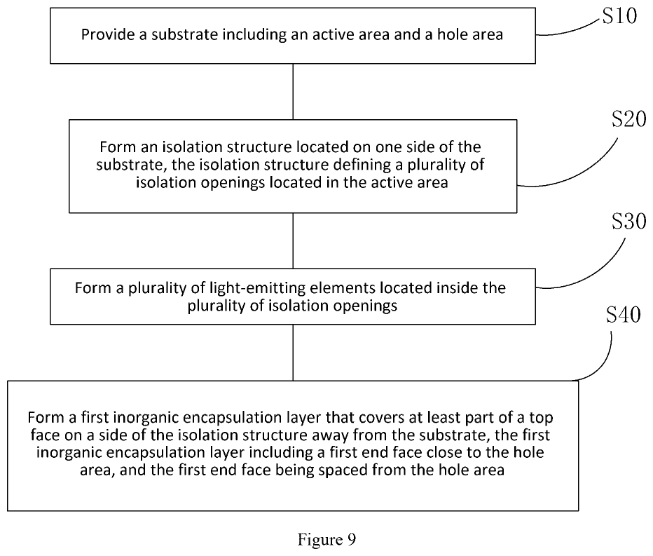

Referring to FIG. 9, in one embodiment of the present application, an embodiment provides a method for preparing a display panel 10, including:
S10, providing a substrate 11, the substrate 11 including an active area 11a and a hole area 11c;
S20, forming an isolation structure 13 located on one side of the substrate 11, the isolation structure 13 defining a plurality of isolation openings 13a located in the active area 11a;
S30, forming a plurality of light-emitting elements 14 located inside the plurality of isolation openings 13a; and
S40, forming a first inorganic encapsulation layer 15 covering at least part of a top surface on a side of the isolation structure 13 away from the substrate 11, where the first inorganic encapsulation layer 15 includes a first end surface 15a close to the hole area 11c, and the first end surface 15a is spaced from the hole area 11c.

In the method for preparing the display panel 10 provided by the embodiment of the present application, by forming the first inorganic encapsulation layer 15 covering at least part of the top surface on the side of the isolation structure 13 away from the substrate 11, and enabling the first end surface 15a of the first inorganic encapsulation layer 15 close to the hole area 11c to be spaced from the hole area 11c, the risk of cracking of the first inorganic encapsulation layer 15 generated in the process of forming an aperture in the hole area 11c of the display panel 10 can be reduced, and the encapsulation reliability of the first inorganic encapsulation layer 15 can be improved, and the reliability in encapsulating the display panel 10 can be improved, thereby improving the reliability of the display panel 10.

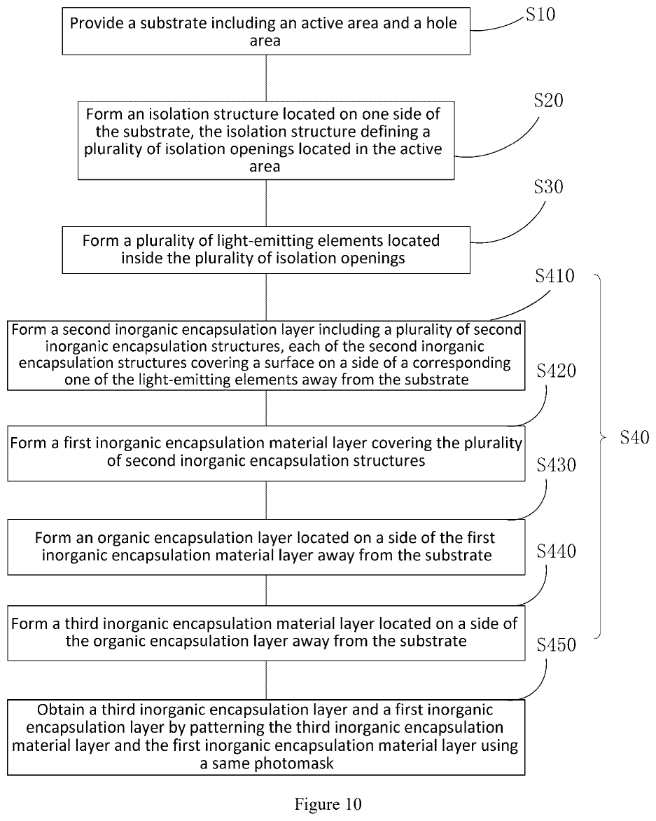

Referring to FIG. 10, in an embodiment, in S40, forming the first inorganic encapsulation layer 15 covering at least part of the top surface on the side of the isolation structure 13 away from the substrate 11 includes:
S410, forming a second inorganic encapsulation layer 16 including a plurality of second inorganic encapsulation structures 161, each of the second inorganic encapsulation structures 161 covering a surface on a side of a corresponding one of the light-emitting elements 14 away from the substrate 11;
S420, forming a first inorganic encapsulation material layer covering the plurality of second inorganic encapsulation structures 161;
S430, forming an organic encapsulation layer 17 located on a side of the first inorganic encapsulation material layer away from the substrate 11;
S440, forming a third inorganic encapsulation material layer located on a side of the organic encapsulation layer 17 away from the substrate 11; and
S450, obtaining a third inorganic encapsulation layer 18 and a first inorganic encapsulation layer 15 by patterning the third inorganic encapsulation material layer and the first inorganic encapsulation material layer using a same photomask.

In the above process, the third inorganic encapsulation layer 18 and the first inorganic encapsulation layer 15 are obtained by patterning the third inorganic encapsulation material layer and the first inorganic encapsulation material layer using the same photomask, i.e., the third inorganic encapsulation layer 18 and the first inorganic encapsulation layer 15 are made in the same process, and the number of mask plates used is decreased, the preparation procedures of the display panel 10 are reduced, and the production cost of the display panel 10 is lowered.

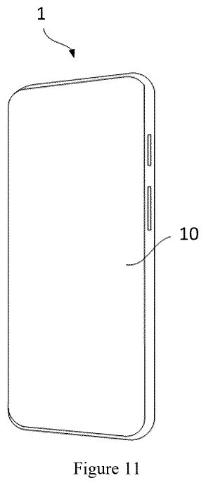

Referring to FIG. 11, in an embodiment of the present application further provides a display device 1, including the display panel 10 as described in any one of the above embodiments. In this way, the display effect of the display device 1 can be improved.

The display device 1 may be a notebook computer, a mobile phone, a wireless device, a personal digital assistant (PDA), a handheld or portable computer, a GPS receiver/navigator, a camera, an MP4 video player, a video camera, a game console, a watch, a clock, a calculator, a television monitor, a flat panel display, a computer monitor, a vehicle display (e.g., an odometer display, etc.), a navigation device, a cockpit controller and/or display, a camera view display (e.g., a display for a rearview camera in a vehicle), an electronic photograph, an electronic billboard or signboard, a projector, or the like.

The above embodiments merely represent several implementations of the present application, giving specifics and details thereof, but should not be understood as limiting the scope of the disclosure thereby. It should be noted that several alterations and improvements could be made without departing from the concept of the present application and these would all fall within the scope of protection of the present application. Therefore, the scope of protection of the present patent application shall be in accordance with the appended claims.

What is claimed is:

1. A display panel, comprising:
a substrate comprising an active area and a hole area;
an isolation structure disposed on one side of the substrate, the isolation structure defining a plurality of isolation openings, and the plurality of isolation openings being located in the active area;
a plurality of light-emitting elements, each of the light-emitting elements being at least partially disposed inside a corresponding one of the isolation openings; and
a first inorganic encapsulation layer covering at least part of a top surface on a side of the isolation structure away from the substrate, the first inorganic encapsulation layer comprising a first end surface close to the hole area, and the first end surface being spaced from the hole area.

2. The display panel according to claim 1, further comprising:
a second inorganic encapsulation layer comprising a plurality of second inorganic encapsulation structures, each of the second inorganic encapsulation structures covering a surface on a side of a corresponding one of the light-emitting elements away from the substrate;
wherein the first inorganic encapsulation layer is located on a side of the second inorganic encapsulation layer away from the substrate;
the first inorganic encapsulation layer covers surfaces on sides of the plurality of second inorganic encapsulation structures away from the substrate; and
the first end surface is spaced from the hole area by not less than 30 um, and the first inorganic encapsulation layer has a thickness ranging from 0.6 um to 1.5 um.

3. The display panel according to claim 1, further comprising:
an organic encapsulation layer located on a side of the first inorganic encapsulation layer away from the substrate and comprising at least one second end surface; and
a third inorganic encapsulation layer located on a side of the organic encapsulation layer away from the substrate;
wherein the at least one second end surface is covered by the third inorganic encapsulation layer and the first inorganic encapsulation layer, and the third inorganic encapsulation layer has a thickness ranging from 0.6 um to 1.5 um.

4. The display panel according to claim 3, wherein the third inorganic encapsulation layer comprises a third end surface close to the hole area,
wherein the third end surface is aligned with the first end surface, and the third end surface and the first end surface are located in the same plane; or
the third end surface coincides with an edge of the hole area.

5. The display panel according to claim 3, wherein the display panel is further provided with a non-active area, the non-active area being at least partially located between the active area and the hole area, and the display panel further comprises:
at least one dam structure located in the non-active area; a distance between the substrate and a surface on a side of the at least one dam structure away from the substrate is greater than a shortest distance between the substrate and a surface on a side of the organic encapsulation layer close to the substrate;
an orthographic projection of the first inorganic encapsulation layer on the at least one dam structure overlaps with an orthographic projection of the third inorganic encapsulation layer on the at least one dam structure; and
the first end surface is located in the non-active area between the at least one dam structure and the hole area.

6. The display panel according to claim 5, wherein the third inorganic encapsulation layer comprises a third end surface close to the hole area,
wherein the third end surface is aligned with the first end surface, and the third end surface is located in the non-active area between the at least one dam structure and the hole area; or
the third end surface coincides with an edge of the hole area, and an orthographic projection of the third inorganic encapsulation layer on the substrate covers an orthographic projection of the at least one dam structure on the substrate.

7. The display panel according to claim 5, further comprising a pixel defining layer, wherein the pixel defining layer is located in the active area and the non-active area and comprises a pixel defining portion, the pixel defining portion defining a plurality of pixel openings, each of the pixel openings being in communication with a corresponding one of the isolation openings, the light-emitting element being at least partially disposed inside a corresponding one of the pixel openings, and the pixel defining portion being located on a side of the first inorganic encapsulation layer close to the substrate;
the pixel defining portion covers at least part of a surface on a side of the at least one dam structure away from the substrate, an orthographic projection of the pixel defining portion on the at least one dam structure overlaps with an orthographic projection of the first inorganic encapsulation layer on the at least one dam structure; and the at least one dam structure is disposed around the active area.

8. The display panel according to claim 3, wherein the display panel is further provided with a non-active area, the non-active area being at least partially located between the active area and the hole area, and the display panel further comprises:
an array layer disposed on one side of the substrate and comprising a plurality of inorganic insulation sub-layers and at least one trench, the plurality of inorganic insulation sub-layers extending from the active area to the non-active area, and the at least one trench being located in the non-active area and extending toward the substrate from a side of the plurality of inorganic insulation sub-layers away from the substrate; wherein the first end surface is located in the non-active area between the at least one trench and the active area; and
the third end surface is aligned with the first end surface, the third end surface is located in the non-active area between the at least one trench and the active area, and a distance between the first end surface and the at least one dam structure is not less than 5 um.

9. The display panel according to claim 8, wherein the third inorganic encapsulation layer comprises a third end surface close to the hole area,
wherein the third end surface coincides with an edge of the hole area, and an orthographic projection of the third inorganic encapsulation layer on the substrate covers an orthographic projection of the at least one trench on the substrate;
an orthographic projection of the first inorganic encapsulation layer on the substrate does not overlap with an orthographic projection of the at least one trench on the substrate;
the at least one trench is disposed around the hole area; and
the at least one trench extends toward the substrate by a first depth from the side of the plurality of inorganic insulation sub-layers away from the substrate, the first depth ranging from 0.6 um to 1.5 um.

10. The display panel according to claim 8, wherein the array layer further comprises a plurality of drive transistors, a plurality of trace connection structures and at least one organic insulation sub-layer, and the display panel further comprises at least one dam structure,
wherein each of the drive transistors comprises a semiconductor layer, a gate, and a first terminal and/or a second terminal, the semiconductor layer, the gate, and the first terminal and/or the second terminal being spaced apart between the plurality of inorganic insulation sub-layers;
the plurality of trace connection structures are disposed in the at least one organic insulation sub-layer, the at least one organic insulation sub-layer is located on the side of the plurality of inorganic insulation sub-layers away from the substrate, and two ends of each of the plurality of trace connection structures are respectively connected to the first terminal of a corresponding one of the drive transistors and a corresponding one of the light-emitting elements;
a distance between the substrate and a surface on a side of the at least one dam structure away from the substrate is greater than a shortest distance between the substrate and a surface on a side of the organic encapsulation layer close to the substrate;
the at least one dam structure and the at least one organic insulation sub-layer are disposed in the same layer;
the at least one dam structure is located in the non-active area between the at least one trench and the active area;
the third end surface is aligned with the first end surface, and the third end surface is located in the non-active area between the at least one dam structure and the at least one trench;
the plurality of inorganic insulation sub-layers comprise a plurality of first inorganic insulation sub-layers, the gates of the drive transistors are located on a side of the plurality of first inorganic insulation sub-layers close to the substrate, and the first terminals of the drive transistors are located on a side of the plurality of first inorganic insulation sub-layers away from the substrate;
the at least one trench runs through the plurality of first inorganic insulation sub-layers; and
the at least one dam structure comprises a plurality of dam structures, a recessed portion is formed between the at least one organic insulation sub-layer and the dam structure close to the at least one organic insulation sub-layer, the recessed portion is filled with the organic encapsulation layer, and a distance between the substrate and a surface on a side of the at least one dam structure away from the substrate is greater than a distance between the substrate and a surface on a side, close to the substrate, of the organic encapsulation layer located in the recessed portion.

11. The display panel according to claim 10, further comprising a pixel defining layer, wherein the pixel defining layer is located in the active area and the non-active area and comprises a pixel defining portion, the pixel defining portion defining a plurality of pixel openings, each of the pixel openings being in communication with a corresponding one of the isolation openings, the light-emitting element being at least partially disposed inside a corresponding one of the pixel openings, and the pixel defining portion being located on a side of the first inorganic encapsulation layer close to the substrate; and an orthographic projection of the pixel defining portion on the substrate covers an orthographic projection of the at least one trench on the substrate.

12. The display panel according to claim 11, wherein the pixel defining portion is at least in contact with the plurality of first inorganic insulation sub-layers located between the at least one dam structure and the hole area;
the first inorganic encapsulation layer is at least in contact with the pixel defining portion located between the at least one dam structure and the at least one trench;
the third inorganic encapsulation layer is at least in contact with the first inorganic encapsulation layer located between the at least one dam structure and the at least one trench; and
the third inorganic encapsulation layer is in contact with the pixel defining portion located between the first end surface and the hole area.

13. The display panel according to claim 10, further comprising:
a pixel defining layer located in the active area and the non-active area and comprising a pixel defining portion, wherein the pixel defining portion defines a plurality of pixel openings, each of the pixel openings is in communication with a corresponding one of the isolation openings, and the light-emitting element is at least partially disposed inside a corresponding one of the pixel openings; the pixel defining portion is located on a side of the first inorganic encapsulation layer close to the substrate;
wherein the pixel defining portion comprises a fourth end surface close to the at least one dam structure, the fourth end surface being located in the non-active area between the at least one organic insulation sub-layer and the at least one dam structure.

14. The display panel according to claim 10, further comprising:
a pixel defining layer located in the active area and the non-active area and comprising a pixel defining portion, the pixel defining portion defining a plurality of pixel openings, each of the pixel openings being in communication with a corresponding one of the isolation openings, the light-emitting element being at least partially disposed inside a corresponding one of the pixel openings, and the pixel defining portion being located on a side of the first inorganic encapsulation layer close to the substrate;
an organic encapsulation layer located on a side of the first inorganic encapsulation layer away from the substrate; and
a third inorganic encapsulation layer located on a side of the organic encapsulation layer away from the substrate;
wherein the pixel defining portion covers at least part of a surface on a side of the at least one dam structure away from the substrate, and an orthographic projection of the pixel defining portion on the at least one dam structure overlaps with an orthographic projection of the third inorganic encapsulation layer on the at least one dam structure.

15. The display panel according to claim 14, wherein the organic encapsulation layer comprises at least one second end surface, the at least one second end surface being covered by the third inorganic encapsulation layer and the pixel defining portion.

16. The display panel according to claim 2, wherein the display panel is further provided with a non-active area, the non-active area is at least partially located between the active area and the hole area, and the isolation structure comprises:
an isolation portion defining the plurality of isolation openings; and
a lap joint portion located in the non-active area, the lap joint portion being connected with a power supply signal trace;
wherein the first inorganic encapsulation layer at least covers part of a top surface on a side of the lap joint portion away from the substrate; and
the light-emitting element comprises a first electrode, a light-emitting functional layer and a second electrode sequentially stacked in a direction away from the substrate, the second electrode overlapping with the isolation portion.

17. The display panel according to claim 16, wherein the plurality of light-emitting elements comprise a first light-emitting element and a second light-emitting element, and the plurality of second inorganic encapsulation structures comprise a first inorganic encapsulation sub-structure and a second inorganic encapsulation sub-structure,
wherein the first inorganic encapsulation sub-structure is disposed on a side of the first light-emitting element away from the substrate and extends from a side wall of the isolation structure to a side of the isolation structure away from the substrate, and the second inorganic encapsulation sub-structure is disposed on a side of the second light-emitting element away from the substrate and extends from a side wall of the isolation structure to the side of the isolation structure away from the substrate; and
an orthographic projection of the first inorganic encapsulation sub-structure on the isolation structure is located outside an orthographic projection of the second inorganic encapsulation sub-structure on the isolation structure, and the first inorganic encapsulation layer covers at least part of a top surface on a side, away from the substrate, of the isolation portion located between the first inorganic encapsulation sub-structure and the second inorganic encapsulation sub-structure.

18. A method for preparing a display panel, comprising:
providing a substrate, the substrate comprising an active area and a hole area;
forming an isolation structure located on one side of the substrate, the isolation structure defining a plurality of isolation openings located in the active area;
forming a plurality of light-emitting elements located inside the plurality of isolation openings; and
forming a first inorganic encapsulation layer covering at least part of a top surface on a side of the isolation structure away from the substrate, wherein the first inorganic encapsulation layer comprises a first end surface close to the hole area, and the first end surface is spaced from the hole area.

19. The method according to claim 18, wherein the forming a first inorganic encapsulation layer covering at least part of a top surface on a side of the isolation structure away from the substrate comprises:
forming a second inorganic encapsulation layer comprising a plurality of second inorganic encapsulation structures, each of the second inorganic encapsulation structures covering a surface on a side of a corresponding one of the light-emitting elements away from the substrate;
forming a first inorganic encapsulation material layer covering the plurality of second inorganic encapsulation structures;
forming an organic encapsulation layer located on a side of the first inorganic encapsulation material layer away from the substrate;
forming a third inorganic encapsulation material layer located on a side of the organic encapsulation layer away from the substrate; and
obtaining a third inorganic encapsulation layer and a first inorganic encapsulation layer by patterning the third inorganic encapsulation material layer and the first inorganic encapsulation material layer using a same photomask.

20. A display device, comprising:
a display panel, comprising:
a substrate comprising an active area and a hole area;
an isolation structure disposed on one side of the substrate, the isolation structure defining a plurality of isolation openings, and the plurality of isolation openings being located in the active area;
a plurality of light-emitting elements, each of the light-emitting elements being at least partially disposed inside a corresponding one of the isolation openings; and
a first inorganic encapsulation layer covering at least part of a top surface on a side of the isolation structure away from the substrate, the first inorganic encapsulation layer comprising a first end surface close to the hole area, and the first end surface being spaced from the hole area.
